(19) United States
(12) Patent Application Publication
(10) Pub. No.: US 2020/0285580 A1
(43) Pub. Date: Sep. 10, 2020

(54) SPECULATIVE MEMORY ACTIVATION

(71) Applicant: Intel Corporation, Santa Clara, CA (US)

(72) Inventors: Lavanya Subramanian, Santa Clara, CA (US); Sreenivas Subramoney, Bangalore (IN); Anant Vithal Nori, Bangalore (IN)

(73) Assignee: Intel Corporation, Santa Clara, CA (US)

(21) Appl. No.: 16/618,070

(22) PCT Filed: Jun. 30, 2017
(86) PCT No.: PCT/US17/40284

§ 371 Date: Nov. 27, 2019

(51) Int. Cl. G06F 12/0842; G11C 11/406; G11C 11/4096

(52) U.S. Cl. CPC G06F 12/0842; G06F 2212/1008; G11C 11/4096; G11C 11/406

(57) ABSTRACT

In one embodiment, an apparatus comprises a processor and a memory controller. The processor is to identify a memory access operation associated with a memory location of a memory. The processor is further to determine that a cache memory does not contain data associated with the memory location. The processor is further to send a memory access notification to a memory controller via a first transmission path. The processor is further to send a memory access request to the memory controller via a second transmission path, wherein the second transmission path is slower than the first transmission path. The memory controller is to receive the memory access notification via the first transmission path, and send a memory activation request based on the memory access notification, wherein the memory activation request comprises a request to activate a memory bank associated with the memory location.

### FIELD OF THE SPECIFICATION

This disclosure relates in general to the field of computer architecture, and more particularly, though not exclusively, to memory access.

### BACKGROUND

The demand for high-performance computing is continuously increasing, and memory latency can be a critical performance bottleneck in modern computing systems, as improvements to memory latency have progressed slower than other aspects of modern computing systems.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

FIG. 1 illustrates an example embodiment of a computing system that uses speculative memory activation to access memory.

FIGS. 2A-B illustrate example embodiments of an express path for speculative memory activation.

FIG. 3 illustrates a flowchart for an example embodiment of speculative memory activation.

FIG. 4 illustrates a flowchart for resolving conflicts between write operations and speculative memory activations.

FIG. 5 illustrates a flowchart for resolving conflicts between memory refresh operations and speculative memory activations.

FIG. 6 illustrates a flowchart for throttling speculative memory activations based on bandwidth.

FIGS. 7A-B, 8, 9, 10, and 11 illustrate example computer architectures that can be used in accordance with embodiments disclosed herein.

### EMBODIMENTS OF THE DISCLOSURE

The following disclosure provides many different embodiments, or examples, for implementing different features of the present disclosure. Specific examples of components and arrangements are described below to simplify the present disclosure. These are, of course, merely examples and are not intended to be limiting. Further, the present disclosure may repeat reference numerals and/or letters in the various examples. This repetition is for the purpose of simplicity and clarity and does not in itself dictate a relationship between the various embodiments and/or configurations discussed. Different embodiments may have different advantages, and no particular advantage is necessarily required of any embodiment.

Example embodiments that may be used to implement the features and functionality of this disclosure are described with reference to the attached FIGURES.

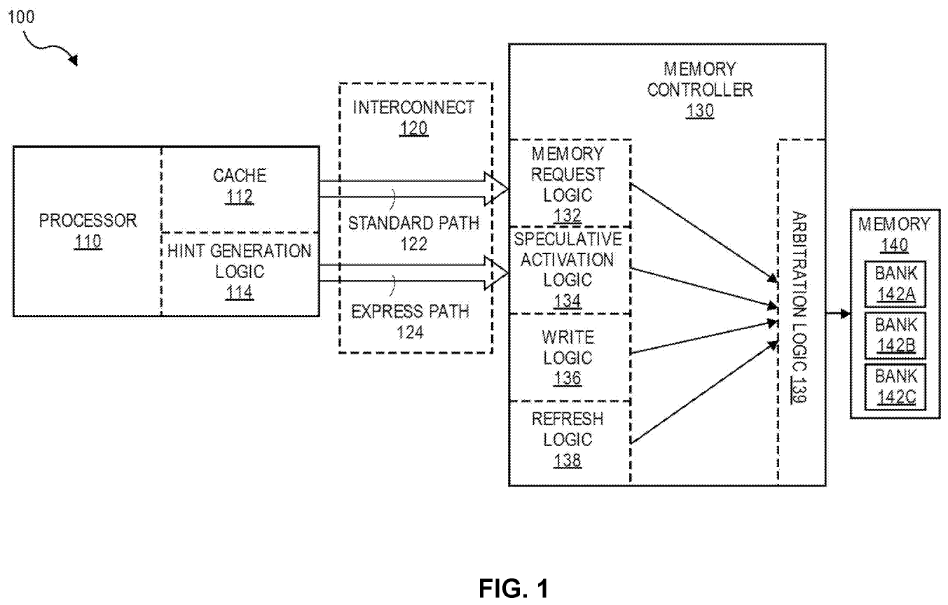

FIG. 1 illustrates an example embodiment of a computing system 100 that uses speculative memory activation to access memory. The demand for high-performance computing is continuously increasing, and memory latency has become a critical performance bottleneck in modern computing systems, as improvements to memory speed have progressed at a much slower rate than other aspects of modern computing systems. Dynamic random access memory (DRAM), for example, is a type of memory used in many computing systems. DRAM latency has only improved by approximately 20% over the past decade and a half, while other aspects of computing systems have improved at significantly higher rates. Moreover, with respect to certain systems and workloads, for memory requests that require access to main memory (e.g., approximately 30% of memory requests for many applications), approximately 80% of the total memory access latency is attributed to DRAM latency. Accordingly, DRAM access latency is often a performance bottleneck.

In some implementations, for example, DRAM is organized into channels, the channels are organized into ranks, and the ranks are organized into banks. Accordingly, the DRAM memory banks are the lowest level of granularity. While accesses to different banks can be performed in parallel, accesses to the same bank are performed serially. Moreover, when accessing a particular data block on a bank, an entire row or memory page (e.g., ˜4-8 kilobytes (KB)) containing the data block is opened and stored in an internal bank structure called a row buffer. This process is referred to as page/row activation and often incurs a high latency (e.g., ˜15-17 nanoseconds (ns) depending on DRAM internal organization and technology considerations). Once a page and/or row is activated, however, subsequent accesses to the same page and/or row (e.g., via the internal row buffer) can be performed significantly faster (e.g., ˜4 ns). Accordingly, the page/row activation latency is the primary source of DRAM access latency and presents a significant obstacle to improving DRAM performance.

In some cases, memory access latency can be addressed at either the memory level or the architecture level. At the architecture level, for example, prefetching can be used to preemptively predict and fetch data that may be needed in the future. In this manner, prefetching can hide a portion of the memory activation latency, assuming the volume, accuracy, and timeliness of prefetched requests is sufficient. Prefetching, however, cannot accurately predict all memory accesses. Moreover, in some cases, a prefetch may be untimely and thus may fail to fully hide the memory access latency. Accordingly, high memory access latency (and activation latency in particular) may continue to hinder memory performance even if prefetching is leveraged. Memory access latency can also be addressed at the memory level. For example, at the memory level, memory can be modified internally to address access latency (e.g., by implementing tiered-latency memory (TL-DRAM) and/or subarray level parallelism (SALP)). However, such modifications require changes to the internal circuitry and implementation of memory (e.g., changes to DRAM circuitry), which presents significant challenges in view of the high cost of memory (e.g., which is often tied to the storage capacity and complexity). Accordingly, complex changes to memory itself may not be a commercially viable solution for reducing memory access latency.

Accordingly, this disclosure presents various embodiments for reducing memory access latency using speculative memory activation. In some embodiments, for example, speculative memory activation may hide memory latency (e.g., DRAM latency) by generating early hints from the processor core to the memory controller to identify physical pages of memory that are likely to be accessed in the immediate future. These hints may be generated, for example, by monitoring memory requests that result in misses in a cache (e.g., a level two cache), and notifying the memory controller that requests for the memory pages associated with the cache misses may be forthcoming. Upon receiving a hint for a particular memory page, the memory controller may then request speculative activation of the corresponding row at all idle memory banks to which the memory page is mapped, as the memory page may be distributed across multiple memory banks (e.g., to enable parallel access to different portions of a memory page). These speculative activations based on the early hints typically occur significantly earlier than when the actual corresponding memory requests are received, thus hiding all or part of the activation latency. In some embodiments, for example, the early hints may be sent to the memory controller via an express path, which may be faster and/or more direct than the standard path used for sending normal memory access requests to the memory controller. Moreover, early hints and speculative activation requests can leverage bandwidth availability that results from memory idleness and under-utilization in both single-threaded and multi-threaded processor configurations.

In the illustrated embodiment of FIG. 1, computing system 100 includes processor 110, interconnect 120, memory controller 130, and memory 140, as described below.

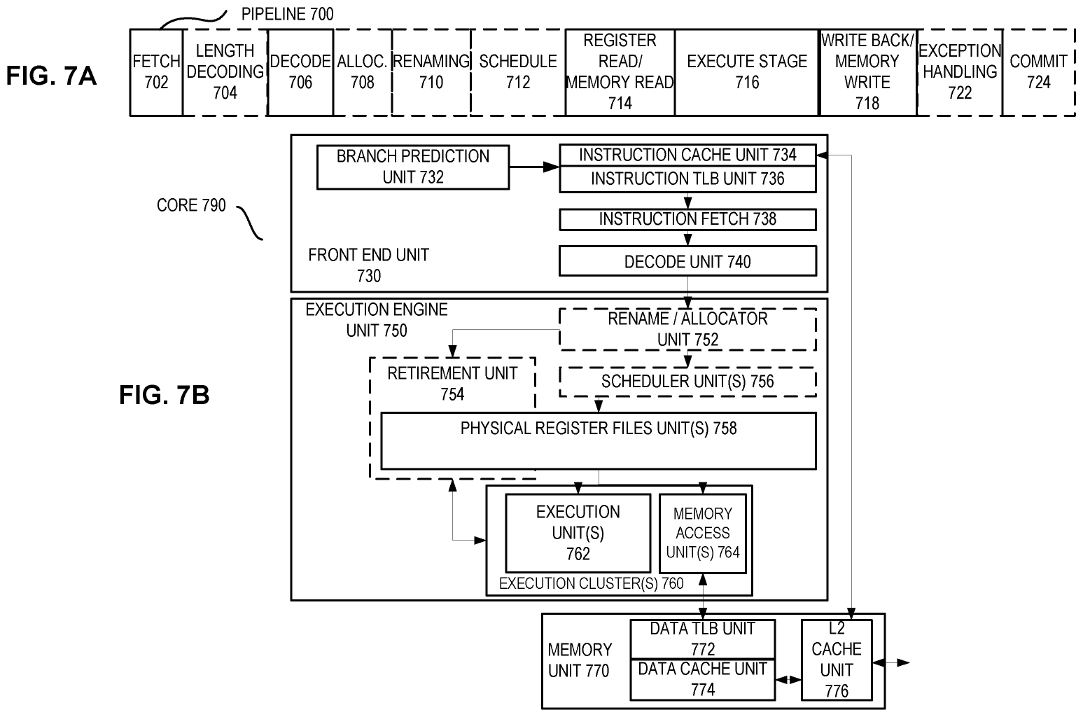

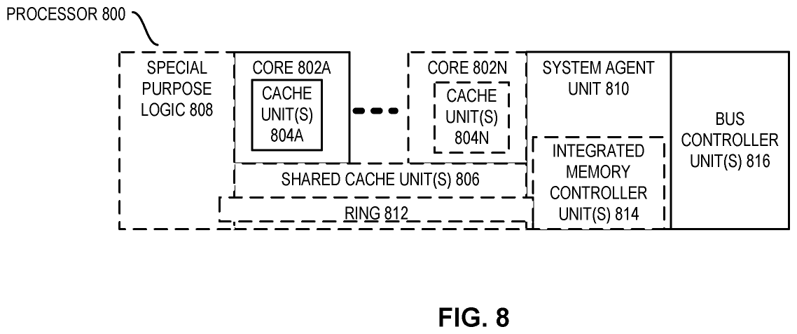

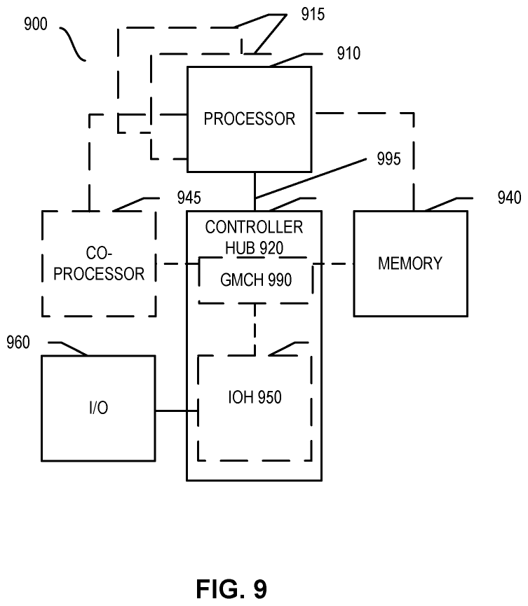

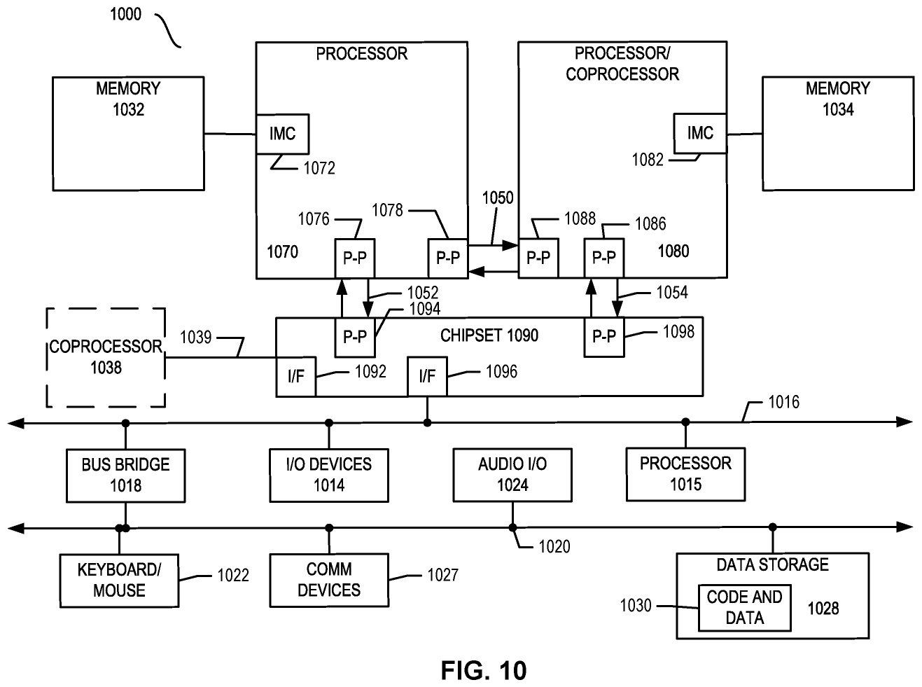

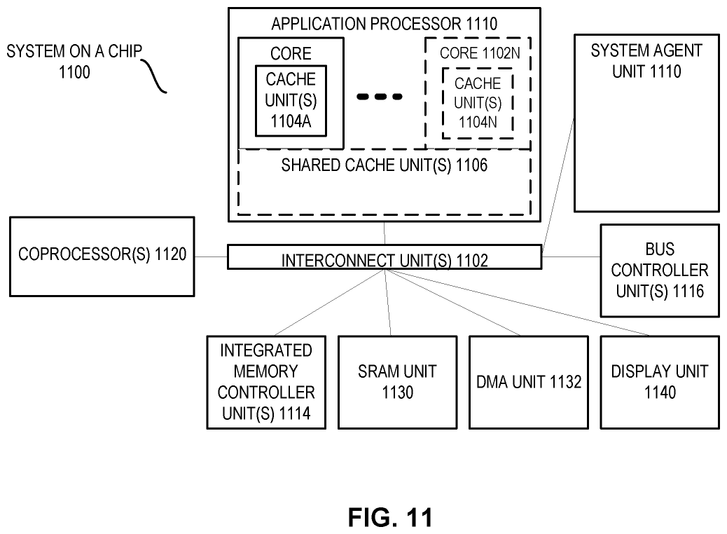

Processor 110 may be used to execute instructions, code, and/or any other form of logic or software, such as instructions associated with a software application. Processor 110 may include any combination of logic or processing elements operable to execute instructions, whether loaded from memory or implemented directly in hardware, such as a microprocessor, digital signal processor, field-programmable gate array (FPGA), graphics processing unit (GPU), programmable logic array (PLA), or application-specific integrated circuit (ASIC), among other examples. In some embodiments, for example, processor 110 (and/or computing system 100) may be implemented using the computer architectures of FIGS. 7-11.

Interconnect 120 may be used to facilitate communication between components of computing system 100, such as between processor 110 and memory controller 130. Interconnect 120 may include any wired or wireless interconnection fabric, bus, line, network, or other communication medium operable to carry data, signals, and/or power among electronic components. In some embodiments, for example, interconnect 120 may be an on-chip interconnect (e.g., an interconnect on the same chip as processor 110 and/or memory controller 130). Moreover, in some embodiments, interconnect 120 may comprise multiple interconnected switching fabrics.

Memory controller 130 may be used to control and/or manage access to memory 140 of system 100. In the illustrated embodiment, memory controller 130 includes memory request logic 132, speculative activation logic 134, write logic 136, refresh logic 138, and arbitration logic 139 (e.g., for arbitrating between different memory access operations). In various embodiments, memory controller 130 and its associated components and functionality may be implemented using any type or combination of hardware and/or software logic, including integrated circuitry, semiconductor chips, accelerators, transistors, application specific integrated circuits (ASICs), field programmable gate arrays (FPGAs), processors (e.g., microprocessors), and/or any software logic, firmware, instructions, or code. In some embodiments, for example, speculative activation logic 134 of memory controller 130 may include circuitry for requesting or performing speculative memory activations.

Memory 140 may be used to store information, such as code and/or data used by processor 110 during execution. Memory 140 may include any type or combination of components capable of storing information, such as random access memory (RAM), dynamic RAM (DRAM), synchronous dynamic RAM (SDRAM), static RAM (SRAM)), and/or any other form of volatile or non-volatile storage. In some embodiments, such as for DRAM memory, memory 140 may be organized into a plurality of memory banks 142.

In the illustrated embodiment, processor 110 is associated with a cache memory 112 and hint generation logic 114. In some embodiments, for example, cache 112 may be a level two (L2) cache. Hint generation logic 114 may include any type or combination of hardware and/or software logic, including integrated circuitry, semiconductor chips, accelerators, transistors, application specific integrated circuits (ASICs), field programmable gate arrays (FPGAs), processors (e.g., microprocessors), and/or any software logic, firmware, instructions, or code. In some embodiments, for example, hint generation logic 114 may include circuitry for generating hints for speculative memory activations.

When a memory access operation needs to be performed, processor 110 issues a memory request, which may trigger a cache lookup in cache 112. If the cache lookup in cache 112 results in a miss, hint generation logic 114 may then generate an early hint or notification, which may be sent to memory controller 130 via express path 124. The early hint, for example, may identify the memory page associated with the cache miss, thus notifying memory controller 130 that a request for the particular memory page may be forthcoming (e.g., assuming the requisite data is not available in any other caches). Moreover, a regular memory access request may also be sent to memory controller 130, but over the standard path 122 used for memory access requests instead of the express path 124 used for hints.

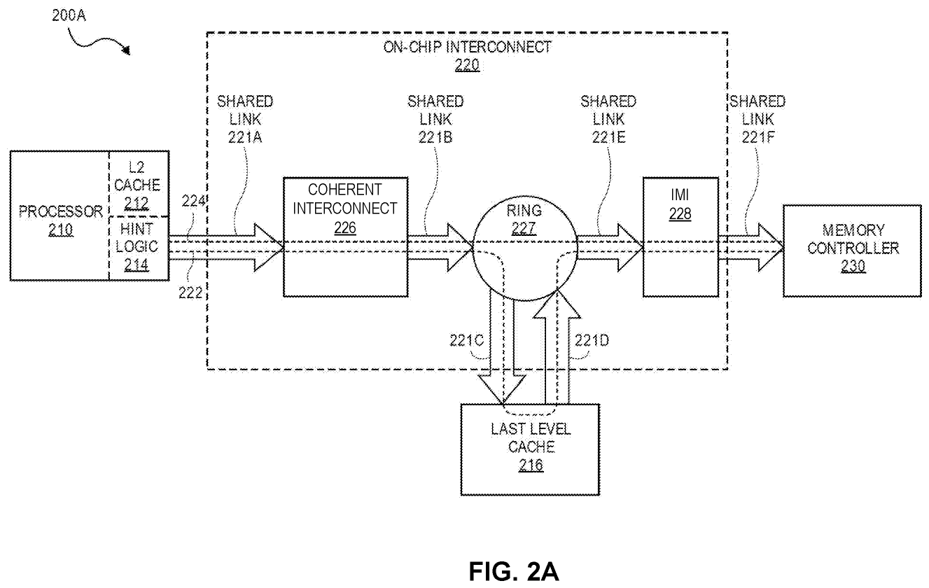

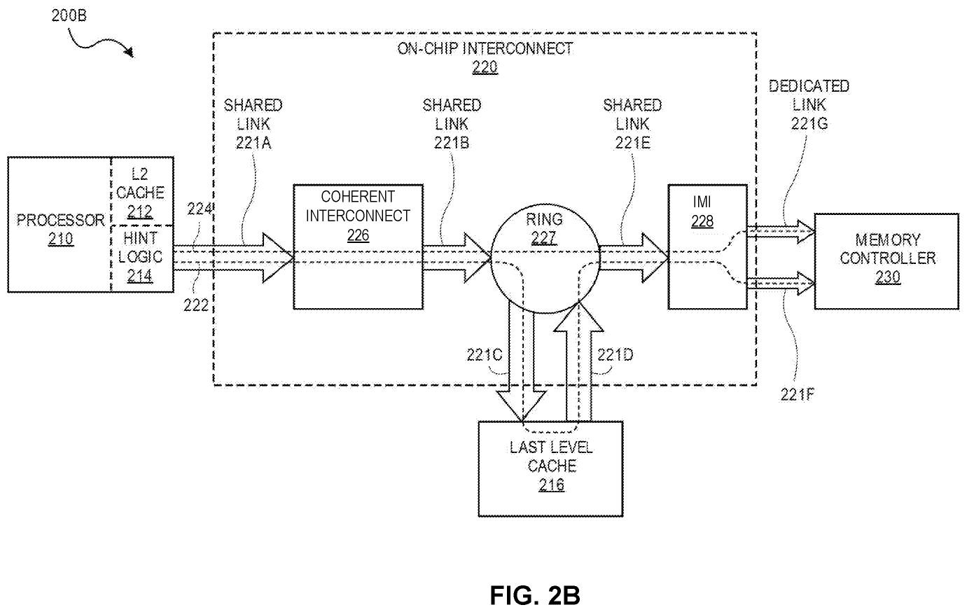

In some embodiments, the express path 124 used for early hints may be faster and/or more direct than the standard path 122 used for regular memory access requests. In some embodiments, for example, express path 124 may be implemented by piggybacking early hints onto regular memory requests sent via standard path 122, while allowing the early hints to bypass the memory request queues and additional cache lookups associated with the regular requests. Moreover, in some embodiments, express path 124 may additionally or alternatively be implemented using one or more dedicated links for sending the early hints to memory controller 130. Accordingly, although FIG. 1 illustrates express path 124 and standard path 122 as separate logical paths, these paths may overlap in their physical implementations, as they may include a combination of shared and dedicated links. Various example embodiments of express path 124 are further illustrated and described in connection with FIGS. 2A-B. When an early hint is received by memory controller 130, the speculative activation logic 134 of memory controller 130 may then request speculative activation of all idle banks 142 of memory 140 that are used to store the memory page associated with the early hint. In this manner, when the regular memory request corresponding to the early hint is received by the memory request logic 132 of memory controller 130 (e.g., via the standard path 122), the appropriate banks 142 of memory 140 are already activated (e.g., the corresponding row of each bank 142 has already been opened and extracted into the internal row buffer). Accordingly, the page/row activation latency is hidden, which significantly reduces the memory access latency.

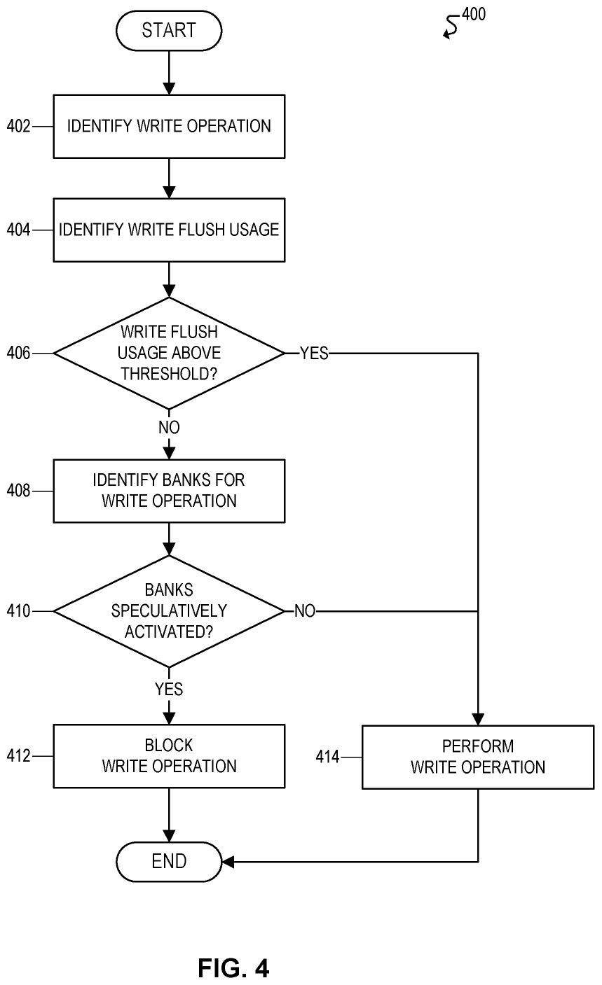

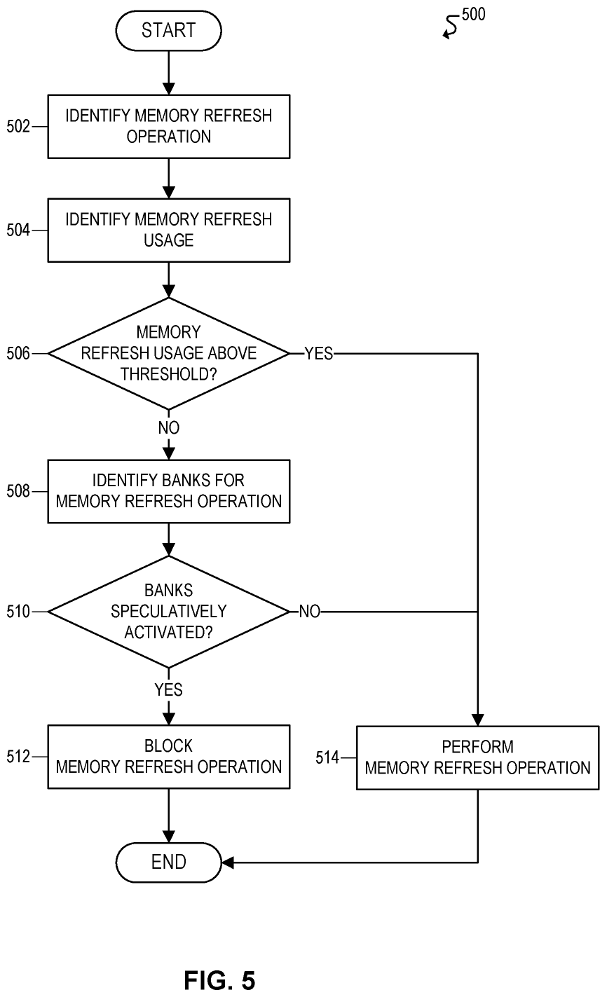

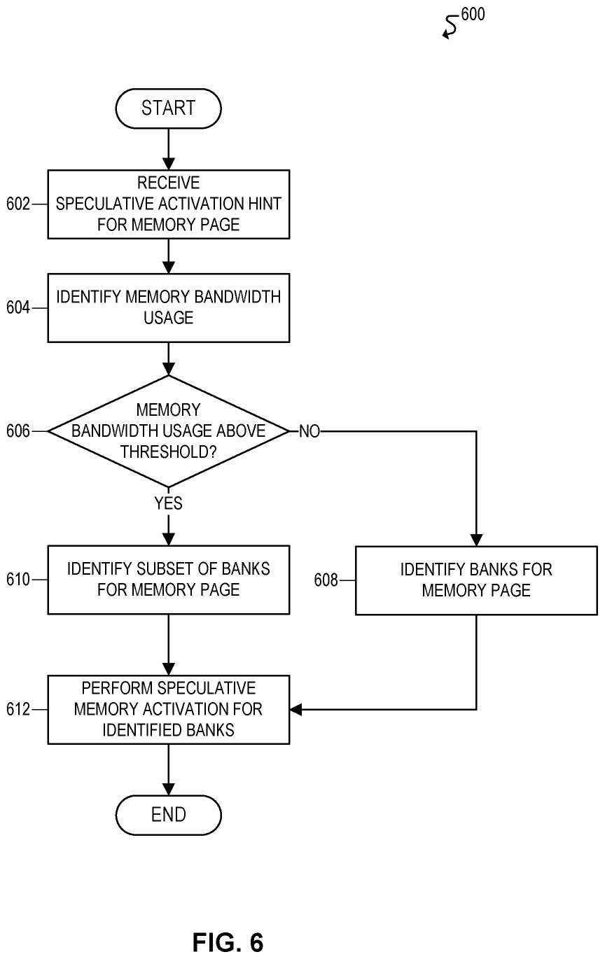

In some cases, however, other memory operations may interfere with speculative memory activations, such as write operations and refresh operations. Accordingly, in some embodiments, memory controller 130 may include additional write logic 136 and/or refresh logic 138 to resolve conflicts with speculative memory activations (e.g., as described further in connection with FIGS. 4 and 5). Moreover, in some embodiments, speculative activation logic 134 may include logic to throttle speculative memory activations when memory bandwidth is low (e.g., as described further in connection with FIG. 6).

TABLE 1 summarizes the additional overhead required for an example embodiment of speculative memory activation (e.g., overhead for additional storage, transmission bandwidth, and/or other logic).

TABLE 1
Overhead For Speculative Memory Activation

| COMPONENT | OVERHEAD |
|---|---|
| Hint generation logic | 14 bytes of storage for page addresses |
| | Logic for hint generation |
| Express path (hint | 7 bytes of additional transmission |
| propagation) | bandwidth for shared links |
| | 7 bytes of transmission bandwidth for |
| | dedicated link(s) |
| Speculative activation logic | 7 bytes of storage for current hint |
| | Logic for speculative memory activations |
| Write logic | 2 bytes of storage per memory channel to |
| | track write drain/flush usage |
| | 1 bit per bank to identify banks that have |
| | been speculatively activated |

For example, hint generation logic 114 may store the page addresses for the current and previous misses in the L2 cache 112 (e.g., 7 bytes of storage per page address, or 14 bytes total, assuming memory addresses are 64-bits and the page offset bits are excluded). Hint generation logic 114 may also require a small number of comparators, gates, and/or other logic to determine if the current and previous misses in cache 114 are for different memory pages, and if so, to issue an early hint. Moreover, express path 124 requires transmission bandwidth for sending an early hint to memory controller 130, which may involve adding transmission bandwidth to any links of standard path 122 that are shared by express path 124 in order to piggyback the early hint with a regular memory request (e.g., an additional 7 bytes per shared link), and/or implementing one or more dedicated links on express path 124 with the requisite transmission bandwidth for sending the early hint (e.g., 7 bytes per dedicated link). Finally, speculative activation logic 134 may only store the current hint (e.g., 7 bytes per memory controller 130), as each hint may be processed immediately upon receipt (e.g., by issuing a speculative memory activation request) and may then be discarded. In other embodiments, however, the hint may be stored for later use, such as if the corresponding banks are not currently idle but subsequently become idle. Speculative activation logic 134 may also require a small number of comparators, gates, and/or other logic to determine which memory banks 142 are idle for the memory page identified by the early hint, and to issue speculative activation requests for the idle memory banks 142.

The described embodiments provide numerous benefits and advantages, including reduced memory access latency and improvements to overall system performance. For example, significant performance improvements can be achieved when using speculative memory activation to send expedited memory access hints from a processor to a memory controller (e.g., using an express path that leverages piggybacking via the regular request path and/or dedicated links). For example, for single-threaded applications that are memory intensive, speculative memory activation may improve performance by approximately 1.5% on average and over 10% in some cases. For multi-threaded applications that are memory intensive, speculative memory activation may improve performance by approximately 0.8% on average and over 5% in some cases. These performance improvements can be achieved on top of any performance increase from conventional prefetching and/or other latency reduction approaches. Moreover, performance can be improved further by performing prefetching from speculatively activated pages of memory, which may increase performance by approximately 0.4% on average and even more in certain circumstances.

Speculative memory activation improves performance by effectively hiding the memory activation latency (e.g., page/row activation latency for DRAM memory banks) for many memory requests. In some cases, significant performance improvements can result even when the average latency reduction is relatively insignificant, as the maximum memory latencies may be reduced significantly for certain critical memory requests. The memory activation latency may be hidden by various aspects of speculative memory activation. For example, speculative memory hints sent via the express path may incur a significantly shorter delay than normal memory requests sent via the regular request path. Moreover, speculative memory activation can be used to activate an entire page of memory upon the first request to that page (e.g., by activating all memory banks 142 containing the memory page). In this manner, for other memory requests to that same page, the latency for speculative memory activations is hidden along with the page activation latency, thus significantly reducing the access latency for those requests. Accordingly, performance gains may be achieved not only for the particular memory request that triggers a speculative memory activation, but also for subsequent memory requests for the same page of memory. In this manner, even when a speculative memory activation is triggered for a memory request that ultimately results in a cache hit (e.g., in a last level cache), performance gains may still be achieved for any subsequent memory requests for the same page of memory. For example, if a speculative memory activation is triggered for a particular memory request after a level two (L2) cache miss, the speculatively activated memory may not be leveraged for that memory request if the request is ultimately satisfied by a last level cache (LLC) hit. However, if a subsequent memory request for the same physical page results in a last level cache (LLC) miss, the speculatively activated memory would still be leveraged for that subsequent memory request. For example, the DRAM bank and row that was speculatively activated for the first request would still be accessed for the subsequent request, thus hiding the DRAM activation latency for the subsequent request.

Moreover, the described embodiments of speculative memory activation provide numerous advantages over other approaches for reducing memory latency. For example, speculative memory activation is orthogonal to conventional prefetching, and thus can be used independently alongside prefetching and may also improve latency for prefetching. For example, while conventional prefetching preemptively fetches data based on past access patterns, speculative memory activation preemptively activates memory based on actual cache misses (e.g., which are likely to imminently result in memory access requests). Accordingly, speculative memory activation leverages the delay that occurs between a cache miss (e.g., an L2 cache miss) and activation of memory (e.g., page/row activation of a DRAM bank). This delay is the result of the queues, reordering, congestion, and additional cache lookups for regular memory requests along the path to the memory controller. The express path allows speculative memory activations to sidestep the delay associated with regular memory requests. Moreover, while conventional prefetching is limited to prefetching a specific cache block, speculative memory activation can be used to activate an entire page of memory, thus significantly reducing access latency for any memory access to that page.

Accordingly, speculative memory activation provides additional performance benefits over conventional prefetching, and can also be used alongside conventional prefetching and/or any other approaches for reducing memory latency. Moreover, in some embodiments, speculative memory activation can be extended to perform prefetching for speculatively activated memory. For example, when a page of memory is speculatively activated (e.g., by opening a row of a memory bank 142 and extracting it into the internal row buffer), the data from the speculatively activated page may be prefetched, for example, into a cache or prefetch buffer, such as a dedicated prefetch buffer in memory controller 130. When a memory access request is subsequently received by memory controller 130, a lookup can be performed in the dedicated prefetch buffer before reading from the appropriate memory banks 142. If the prefetch buffer contains the requisite data, the data can be obtained from the prefetch buffer without having to read the appropriate memory banks 142. If the prefetch buffer does not contain the requisite data, the data may then be obtained by reading the appropriate memory banks 142.

Moreover, unlike approaches that require memory design modifications, such as tiered-latency memory (TL-DRAM) and/or subarray level parallelism (SALP), the described embodiments can be implemented in a cost-efficient manner and without any modifications to memory. In this manner, the described embodiments can be leveraged to provide various cost and performance related benefits for a computing system with any type of memory (e.g., DRAM).

While FIG. 1 is described as containing or being associated with a plurality of elements, not all elements illustrated within system 100 of FIG. 1 may be utilized in each alternative implementation of the present disclosure. Additionally, one or more of the elements described in connection with the examples of FIG. 1 may be located external to system 100, while in other instances, certain elements may be included within or as a portion of one or more of the other described elements, as well as other elements not described in the illustrated implementation. Further, certain elements illustrated in FIG. 1 may be combined with other components, as well as used for alternative or additional purposes in addition to those purposes described herein.

FIGS. 2A and 2B illustrate example embodiments of an express path for speculative memory activation. In some embodiments, for example, the express path of FIG. 2A or FIG. 2B may be used to implement express path 124 of FIG. 1.

FIGS. 2A and 2B illustrate a processor 210, on-chip interconnect 220, and memory controller 230. In some embodiments, these components may be similar to corresponding components in FIG. 1. On-chip interconnect 220 may include any type and/or combination of interconnects, links, interfaces, and/or other connection topologies (e.g., ring, mesh, bus, and/or star interconnect topologies). For example, in the illustrated embodiment, on-chip interconnect 220 further includes a coherent interconnect 226, ring interconnect 227, and an interconnect memory interface (IMI) 228 (e.g., to provide an interface between interconnect 220 and memory controller 230), along with a plurality of transmission links 221. In some embodiments, on-chip interconnect 220 may be used to connect the processor cores (e.g., processor 210), last level cache 216, and memory controller 230. For example, on-chip interconnect 220 may be used to send regular memory requests and/or speculative memory activation hints from processor 210 to memory controller 230, and/or perform cache lookups in last level cache 216.

A regular memory request, for example, may be sent from processor 210 to memory controller 230 via on-chip interconnect 220. The memory request may be sent through on-chip interconnect 220, for example, using the standard path 222 for memory requests. For example, standard path 222 may be used to send the memory request from processor 210 to the coherent interconnect 226 (via link 221a), then to ring 227 (via link 221b), then to last level cache 216 (via link 221c) to perform a last level cache lookup, then back to ring 227 (via link 221d), then to IMI 228 (via link 221e), and finally to memory controller 230 (via link 221f).

A hint for a speculative memory activation may also be sent from processor 210 to memory controller 230 via on-chip interconnect 220. The hint may be sent by hint logic 214 of processor 210, for example, after a cache miss occurs in the level two (L2) cache 212. However, the hint may be sent through on-chip interconnect 220 using an express path 224 for expediting transmission of the hint (e.g., rather than the standard path 222 used for regular memory requests). In some embodiments, for example, express path 224 may be implemented using shared transmission links, dedicated transmission links, or both. For example, express path 224 may leverage one or more shared links of standard path 222 to piggyback hints onto regular memory requests traveling on standard path 222. For example, a hint may be sent over a shared link by piggybacking it onto the next memory request transmitted over that link (e.g., the memory request at the front of a transmission queue for that link), thus jumping ahead of all other memory requests pending at that link. Express path 224 may also include one or more dedicated links for sending hints, which are not shared by standard path 222 for regular memory requests. In this manner, by using piggybacking over shared links and/or dedicated links, express path 224 allows hints to bypass the delays associated with regular memory requests, such as congestion, queues, reordering or other processing, and/or additional cache lookups (e.g., last level cache 216 lookups).

FIG. 2A illustrates an embodiment of an express path 224 implemented entirely using shared links and piggybacking. In the illustrated embodiment, for example, express path 224 leverages certain shared links of standard path 222 (e.g., links 221a,b,e,f) to send hints from processor 210 to memory controller 230. For example, a hint sent on express path 224 travels from processor 210 to coherent interconnect 226 (via link 221a), then to ring 227 (via link 221b), then to IMI 228 (via link 221e), and finally to memory controller 230 (via link 221f). The hint may be sent over these links, for example, by piggybacking onto regular memory request(s) that are sent on standard path 222. For example, a backlog of regular memory requests may be waiting to be transmitted to memory controller 230 after missing at the L2 cache 212. The next memory request that is transmitted from the backlog may be selected based on varying criteria, such as a queue order, an arbitration or scheduling policy, and so forth. Accordingly, the hint may be piggybacked onto the next memory request selected for transmission (e.g., the winning request from the queue and/or arbitration), thus causing both the hint and memory request to be sent from processor 210 to coherent interconnect 226 (via shared link 221a). In this manner, the hint jumps ahead of the backlog of memory requests that resulted in misses at the L2 cache 212. When the hint reaches coherent interconnect 226, however, there may be another queue of memory requests that are waiting to be transmitted. Accordingly, the hint may once again piggyback onto the next memory request that is sent from coherent interconnect 226 to ring interconnect 227 (via shared link 221b). In some embodiments, the hint can then be sent through ring interconnect 227 regardless of whether a valid packet or memory request is being sent during the same cycle, as a ring packet may be continuously circulating through ring interconnect 227. Accordingly, the hint may be sent through ring interconnect 227 directly to IMI 228 (via shared link 221e), thus bypassing the last level cache 216 lookup that is performed for regular memory requests. Once the hint reaches IMI 228, the hint may once again be piggybacked onto the next memory request that is sent from IMI 228 to memory controller 230 (via shared link 221f).

Although piggybacking allows a hint to bypass queues and other sources of delay incurred for regular memory requests, it also requires the hint to wait until memory requests are ready to be transmitted at each link of express path 224 that uses piggybacking. Moreover, waiting on a memory request can increase latency along express path 224, particularly further downstream (e.g., at IMI 228 and beyond) where the traffic for memory requests reduces significantly compared to upstream (e.g., at the L2 cache 212). Accordingly, FIG. 2B illustrates an alternative embodiment of an express path that eliminates the downstream piggyback latency.

FIG. 2B illustrates an embodiment of an express path 224 implemented using shared links and a dedicated link. The express path of FIG. 2B is similar to the express path of FIG. 2A, with the addition of a dedicated link 221f implemented between IMI 228 and memory controller 230. Dedicated link 221f allows a hint to be transmitted directly from IMI 228 to memory controller 230, for example, instead of piggybacking the hint onto a regular memory request via a shared link (as done in the express path of FIG. 2A). In this manner, the piggyback latency is eliminated at this downstream link of express path 224, where piggybacking can incur longer delays when waiting for memory requests since there is less traffic.

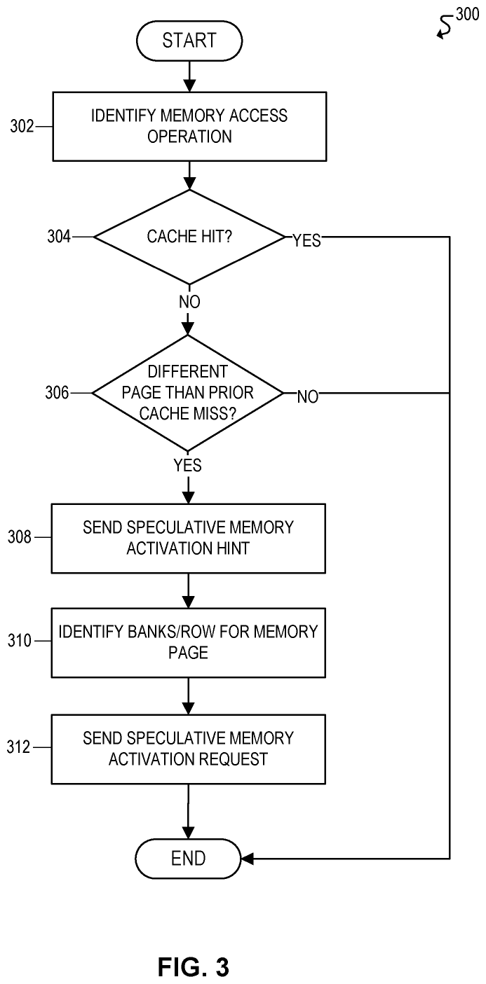

FIG. 3 illustrates a flowchart 300 for an example embodiment of speculative memory activation. Flowchart 300 may be implemented, for example, using the embodiments and functionality described throughout this disclosure.

The flowchart may begin at block 302 by identifying a memory access operation. The memory access operation, for example, could be an operation to read a particular location of memory (e.g., DRAM).

The flowchart may then proceed to block 304 to determine whether a cache (e.g., a level two cache) contains data for the memory location associated with the memory access operation. If it is determined at block 304 that the cache contains data for the memory location, then the memory access operation can be performed using the data in the cache, and thus no memory pages need to be speculatively activated. Accordingly, at this point, the flowchart may be complete.

However, if it is determined at block 304 that the cache does NOT contain data for the memory location, the flowchart may then proceed to block 306 to determine whether the memory location is on a different memory page than the previous cache miss. For example, if the memory location is on a different memory page than the previous cache miss, then a new memory page is potentially being accessed, and thus a speculative memory activation hint for that memory page may not have been sent yet. Accordingly, the flowchart may proceed to block 308 to send a speculative memory activation hint for the memory page. However, if the memory location is on the same memory page as the previous cache miss, then a speculative memory activation hint for that memory page may have already been sent, and thus it may be unnecessary to send another hint. Accordingly, at this point, the flowchart may be complete. This is one possible approach to identify access to new physical pages of memory that may not already be speculatively activated. Other approaches, however, may also be used. For example, in some embodiments, a window of recently accessed memory pages may be tracked to avoid sending duplicative speculative activation hints for those memory pages.

At block 308, a speculative memory activation hint for the memory page is sent to the memory controller. The hint, for example, may be a notification to the memory controller that the particular memory page may be accessed in the immediate future. In some embodiments, for example, the hint may identify the address of the memory page.

The flowchart may then proceed to block 310 to identify the memory banks and row that are used to store the memory page. In some embodiments, for example, a memory page may be stored on a particular row of multiple memory banks.

The flowchart may then proceed to block 312 to send speculative memory activation request(s), for example, to activate the row of the memory banks used to store the memory page. In this manner, the memory banks are preemptively activated before a corresponding regular memory access request is received, thus hiding the memory activation latency. Moreover, in some embodiments, speculative memory activation request(s) may only be sent for memory banks that are idle, thus avoiding conflicts with memory banks that are currently active.

At this point, the flowchart may be complete. In some embodiments, however, the flowchart may restart and/or certain blocks may be repeated. For example, in some embodiments, the flowchart may restart at block 302 to continue processing memory access operations.

FIG. 4 illustrates a flowchart 400 for resolving conflicts between write operations and speculative memory activations. Flowchart 400 may be implemented, for example, using the embodiments and functionality described throughout this disclosure.

In some embodiments, memory write operations may interfere with speculative memory activates, such as dirty cache write-back requests that involve the same memory bank(s) as speculative memory activates. In some cases, for example, dirty cache write-back requests may be queued in a write buffer that is flushed or drained periodically (e.g., when the buffer is full or almost full) since write-back requests are not on the critical path of execution. However, in order to reduce long write buffer drain periods, some write operations may be performed opportunistically during non-write drain periods, for example, when there are no pending read operations. Such opportunistic write operations can interfere with speculative memory activations, however, by closing speculatively activated memory banks/rows before they are read. Accordingly, in some cases, opportunistic write operations may be blocked if they involve memory banks that have been speculatively activated. However, blocking opportunistic write operations may fill up the write buffer and result in frequent write drains, thus degrading overall performance. Accordingly, write operations must be handled in an efficient manner that resolves these various types of conflicts with speculative memory activations. In some embodiments, for example, flowchart 400 may be used to resolve conflicts between write operations and speculative memory activations.

The flowchart may begin at block 402 by identifying a memory write operation. In some cases, for example, the memory write operation may be an opportunistic write-back request for a dirty cache entry.

The flowchart may then proceed to block 404 to identify the current write flush usage. The current write flush usage, for example, may identify the amount of time that is being spent draining or flushing the write buffer. For example, in some embodiments, the percentage of time spent in write drain or write flush mode for a particular memory channel can be calculated as follows:

$$write flush mode usage \% = \frac{\# cycles in write flush mode}{\# total cycles} * 100$$

The flowchart may then proceed to block 406 to determine whether the current write flush usage is above a threshold. For example, if the percentage of time spent in write flush mode exceeds a particular threshold, then the memory controller may be spending significant time draining writes, and thus performance may be hurt even further if an opportunistic write request is delayed. However, if the threshold is not exceeded, then an acceptable amount of time is being spent draining writes, and thus the opportunistic write can be blocked/delayed without hurting performance. In some embodiments, for example, a threshold in the range of 0-0.3% may result in a good performance balance.

Accordingly, if the write flush usage exceeds the threshold, the flowchart may proceed to block 414 to perform the write operation. However, if the write flush usage is below the threshold, the flowchart may proceed to block 408 to further evaluate whether to perform or block the write operation.

At block 408, the memory banks associated with the write operation may be identified, and the flowchart may then proceed to block 410 to determine whether those memory banks have been speculatively activated. For example, if a memory page has been opened by speculatively activating a memory bank that is needed for the write operation, the write operation may be blocked/delayed to avoid closing the speculatively activated memory bank/row before it has been read.

Accordingly, if the memory banks associated with the write operation have been speculatively activated, the flowchart may proceed to block 412 to block the write operation. However, if the memory banks associated with the write operation have NOT been speculatively activated, the flowchart may proceed to block 414 to perform the write operation.

At this point, the flowchart may be complete. In some embodiments, however, the flowchart may restart and/or certain blocks may be repeated. For example, in some embodiments, the flowchart may restart at block 402 to continue processing cache flush operations.

FIG. 5 illustrates a flowchart 500 for resolving conflicts between memory refresh operations and speculative memory activations. Flowchart 500 may be implemented, for example, using the embodiments and functionality described throughout this disclosure.

In some embodiments, memory refresh operations may interfere with speculative memory activations in a similar manner as write operations. For example, memory refresh operations may be used to refresh certain memory locations to avoid losing data. Panic refreshes are memory refresh operations that must be performed immediately to avoid losing data, while opportunistic refresh operations are memory refresh operations that are performed further in advance. These memory refresh operations can interfere with speculative memory activations by closing speculatively activated memory banks/rows before they are read. Thus, in some cases, opportunistic refresh operations may need to be blocked/delayed if they involve memory banks that have been speculatively activated. However, blocking opportunistic refresh operations may result in spending excessive time performing panic refreshes to avoid data loss. Accordingly, in some embodiments, flowchart 500 may be used to resolve conflicts between memory refresh operations and speculative memory activations.

The flowchart may begin at block 502 by identifying a memory refresh operation. In some cases, for example, the memory refresh operation may be an opportunistic memory refresh.

The flowchart may then proceed to block 504 to identify the current memory refresh usage. The current memory refresh usage, for example, may identify the amount of time that is being spent performing panic refreshes in order to avoid imminent data loss. For example, in some embodiments, the percentage of time spent performing panic refreshes can be calculated as follows:

$$memory refresh usage \% = \frac{\# cycles performing panic refreshes}{\# total cycles} * 100$$

The flowchart may then proceed to block 506 to determine whether the current memory refresh usage is above a threshold. For example, if the percentage of time spent performing panic refreshes exceeds a particular threshold, then an excessive number of panic refreshes are being performed, and thus it may be undesirable to delay any opportunistic memory refreshes. However, if the threshold is not exceeded, then the amount of time being spent performing panic refreshes is acceptable, and thus opportunistic memory refreshes can be blocked/delayed without hurting performance.

Accordingly, if the memory refresh usage exceeds the threshold, the flowchart may proceed to block 514 to perform the memory refresh operation. However, if the memory refresh usage is below the threshold, the flowchart may proceed to block 508 to further evaluate whether to perform or block the memory refresh operation.

At block 508, the memory banks associated with the memory refresh operation may be identified, and the flowchart may then proceed to block 510 to determine whether those memory banks have been speculatively activated. For example, if a memory page has been opened by speculatively activating a memory bank that is needed for the memory refresh operation, the memory refresh operation may be blocked/delayed to avoid closing the speculatively activated memory bank/row before it has been read.

Accordingly, if the memory banks associated with the memory refresh operation have been speculatively activated, the flowchart may proceed to block 512 to block the memory refresh operation. However, if the memory banks associated with the memory refresh operation have NOT been speculatively activated, the flowchart may proceed to block 514 to perform the memory refresh operation.

At this point, the flowchart may be complete. In some embodiments, however, the flowchart may restart and/or certain blocks may be repeated. For example, in some embodiments, the flowchart may restart at block 502 to continue processing memory refresh operations.

FIG. 6 illustrates a flowchart 600 for throttling speculative memory activations based on bandwidth. Flowchart 600 may be implemented, for example, using the embodiments and functionality described throughout this disclosure.

In some cases (e.g., for certain systems and/or workloads), multiple accesses to the same memory page relatively close in time involve a single bank ˜60% of the time, two banks ˜25% of the time, and three or more banks ˜15% of the time. Thus, approximately 40% of those accesses to the memory page involve multiple banks. Accordingly, in some embodiments, all banks associated with a memory page may be speculatively activated the first time the memory page is accessed, thus enabling greater potential for hiding activation latency. At some point, however, over-speculation may hurt performance (e.g., by increasing latency for baseline demands, prefetching, and so forth).

In single-threaded scenarios, for example, there is significant idle time and underutilization of queues and resources along the path from a processor to a memory controller (e.g., through the level two (L2) cache, queues/super queues, fabric, and last level caches). This underutilization is a key enabler for sending speculative activation hints and issuing corresponding speculative activation requests at the memory controller. In multi-threaded scenarios, however, there may be less idle time and underutilization, particularly at the memory controller where the speculative activations are issued. Accordingly, in some embodiments, the number of speculative activations may be throttled in certain circumstances. For example, accesses to a particular memory page that occur relatively close in time, and that involve multiple banks, involve the same set of banks 40% of the time, on average. Accordingly, in some embodiments, these predictable access patterns can be leveraged to throttle speculative memory activations in certain circumstances. In some embodiments, for example, flowchart 600 may be used to throttle speculative memory activations when memory bandwidth is scarce.

The flowchart may begin at block 602 by receiving a speculative activation hint for a particular memory page. The speculative activation hint, for example, may be sent to a memory controller after a miss in the level two (L2) cache.

The flowchart may then proceed to block 604 to identify the current memory bandwidth usage, and then to block 606 to determine whether the memory bandwidth usage is above a particular threshold. If the memory bandwidth usage does NOT exceed the threshold, then it may be unnecessary to throttle speculative memory activations. Accordingly, the memory controller may decide to speculatively activate all memory banks associated with the memory page identified by the early hint. If the memory bandwidth usage does exceed the threshold, then it may be desirable to throttle the number of speculative memory activations. Accordingly, the memory controller may only speculatively activate a subset of the memory banks associated with the memory page identified by the early hint. For example, the memory controller may only activate memory bank(s) that are required for a particular memory access operation, or may only activate certain memory banks that are common to multiple memory access operations.

Accordingly, if the memory bandwidth usage exceeds the threshold, the flowchart may proceed to block 608 to identify all memory banks associated with the memory page. However, if the memory bandwidth usage does NOT exceed the threshold, the flowchart may proceed to block 610 to identify a subset of the memory banks associated with the memory page, as described above.

The flowchart may then proceed to block 612 to perform a speculative memory activation for the identified memory banks.

At this point, the flowchart may be complete. In some embodiments, however, the flowchart may restart and/or certain blocks may be repeated. For example, in some embodiments, the flowchart may restart at block 602 to continue processing speculative memory activation hints.

Example Computing Architectures

FIGS. 7-11 illustrate example computer architectures that can be used in accordance with embodiments disclosed herein. For example, in various embodiments, the computer architectures of FIGS. 7-11 may be used in conjunction with, and/or may be used to implement, the speculative memory activation functionality described throughout this disclosure. Other computer architectures, system designs, and configurations known in the arts for laptops, desktops, handheld PCs, personal digital assistants, engineering workstations, servers, network devices, network hubs, switches, embedded processors, digital signal processors (DSPs), graphics devices, video game devices, set-top boxes, micro controllers, cell phones, portable media players, hand held devices, and various other electronic devices, are also suitable. In general, a huge variety of systems or electronic devices capable of incorporating a processor and/or other execution logic as disclosed herein are generally suitable.

FIG. 7A is a block diagram illustrating both an exemplary in-order pipeline and an exemplary register renaming, out-of-order issue/execution pipeline according to embodiments of the invention. FIG. 7B is a block diagram illustrating both an exemplary embodiment of an in-order architecture core and an exemplary register renaming, out-of-order issue/execution architecture core to be included in a processor according to embodiments of the invention. The solid lined boxes in FIGS. 7A-B illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 7A, a processor pipeline 700 includes a fetch stage 702, a length decode stage 704, a decode stage 706, an allocation stage 708, a renaming stage 710, a scheduling (also known as a dispatch or issue) stage 712, a register read/memory read stage 714, an execute stage 716, a write back/memory write stage 718, an exception handling stage 722, and a commit stage 724.

FIG. 7B shows processor core 790 including a front end unit 730 coupled to an execution engine unit 750, and both are coupled to a memory unit 770. The core 790 may be a reduced instruction set computing (RISC) core, a complex instruction set computing (CISC) core, a very long instruction word (VLIW) core, or a hybrid or alternative core type. As yet another option, the core 790 may be a special-purpose core, such as, for example, a network or communication core, compression engine, coprocessor core, general purpose computing graphics processing unit (GPGPU) core, graphics core, or the like.

The front end unit 730 includes a branch prediction unit 732 coupled to an instruction cache unit 734, which is coupled to an instruction translation lookaside buffer (TLB) 736, which is coupled to an instruction fetch unit 738, which is coupled to a decode unit 740. The decode unit 740 (or decoder) may decode instructions, and generate as an output one or more micro-operations, micro-code entry points, microinstructions, other instructions, or other control signals, which are decoded from, or which otherwise reflect, or are derived from, the original instructions. The decode unit 740 may be implemented using various different mechanisms. Examples of suitable mechanisms include, but are not limited to, look-up tables, hardware implementations, programmable logic arrays (PLAs), microcode read only memories (ROMs), etc. In one embodiment, the core 790 includes a microcode ROM or other medium that stores microcode for certain macroinstructions (e.g., in decode unit 740 or otherwise within the front end unit 730). The decode unit 740 is coupled to a rename/allocator unit 752 in the execution engine unit 750.

The execution engine unit 750 includes the rename/allocator unit 752 coupled to a retirement unit 754 and a set of one or more scheduler unit(s) 756. The scheduler unit(s) 756 represents any number of different schedulers, including reservations stations, central instruction window, etc. The scheduler unit(s) 756 is coupled to the physical register file(s) unit(s) 758. Each of the physical register file(s) units 758 represents one or more physical register files, different ones of which store one or more different data types, such as scalar integer, scalar floating point, packed integer, packed floating point, vector integer, vector floating point, status (e.g., an instruction pointer that is the address of the next instruction to be executed), etc. In one embodiment, the physical register file(s) unit 758 comprises a vector registers unit, a write mask registers unit, and a scalar registers unit. These register units may provide architectural vector registers, vector mask registers, and general purpose registers. The physical register file(s) unit(s) 758 is overlapped by the retirement unit 754 to illustrate various ways in which register renaming and out-of-order execution may be implemented (e.g., using a reorder buffer(s) and a retirement register file(s); using a future file(s), a history buffer(s), and a retirement register file(s); using a register maps and a pool of registers; etc.). The retirement unit 754 and the physical register file(s) unit(s) 758 are coupled to the execution cluster(s) 760. The execution cluster(s) 760 includes a set of one or more execution units 762 and a set of one or more memory access units 764. The execution units 762 may perform various operations (e.g., shifts, addition, subtraction, multiplication) and on various types of data (e.g., scalar floating point, packed integer, packed floating point, vector integer, vector floating point). While some embodiments may include a number of execution units dedicated to specific functions or sets of functions, other embodiments may include only one execution unit or multiple execution units that all perform all functions. The scheduler unit(s) 756, physical register file(s) unit(s) 758, and execution cluster(s) 760 are shown as being possibly plural because certain embodiments create separate pipelines for certain types of data/operations (e.g., a scalar integer pipeline, a scalar floating point/packed integer/packed floating point/vector integer/vector floating point pipeline, and/or a memory access pipeline that each have their own scheduler unit, physical register file(s) unit, and/or execution cluster—and in the case of a separate memory access pipeline, certain embodiments are implemented in which only the execution cluster of this pipeline has the memory access unit(s) 764). It should also be understood that where separate pipelines are used, one or more of these pipelines may be out-of-order issue/execution and the rest in-order.

The set of memory access units 764 is coupled to the memory unit 770, which includes a data TLB unit 772 coupled to a data cache unit 774 coupled to a level 2 (L2) cache unit 776. In one exemplary embodiment, the memory access units 764 may include a load unit, a store address unit, and a store data unit, each of which is coupled to the data TLB unit 772 in the memory unit 770. The instruction cache unit 734 is further coupled to a level 2 (L2) cache unit 776 in the memory unit 770. The L2 cache unit 776 is coupled to one or more other levels of cache and eventually to a main memory.

By way of example, the exemplary register renaming, out-of-order issue/execution core architecture may implement the pipeline 700 as follows: 1) the instruction fetch 738 performs the fetch and length decoding stages 702 and 704; 2) the decode unit 740 performs the decode stage 706; 3) the rename/allocator unit 752 performs the allocation stage 708 and renaming stage 710; 4) the scheduler unit(s) 756 performs the schedule stage 712; 5) the physical register file(s) unit(s) 758 and the memory unit 770 perform the register read/memory read stage 714; the execution cluster 760 perform the execute stage 716; 6) the memory unit 770 and the physical register file(s) unit(s) 758 perform the write back/memory write stage 718; 7) various units may be involved in the exception handling stage 722; and 8) the retirement unit 754 and the physical register file(s) unit(s) 758 perform the commit stage 724.

The core 790 may support one or more instructions sets (e.g., the x86 instruction set (with some extensions that have been added with newer versions); the MIPS instruction set of MIPS Technologies of Sunnyvale, Calif.; the ARM instruction set (with optional additional extensions such as NEON) of ARM Holdings of Sunnyvale, Calif.), including the instruction(s) described herein. In one embodiment, the core 790 includes logic to support a packed data instruction set extension (e.g., AVX1, AVX2), thereby allowing the operations used by many multimedia applications to be performed using packed data.

It should be understood that the core may support multithreading (executing two or more parallel sets of operations or threads), and may do so in a variety of ways including time sliced multithreading, simultaneous multithreading (where a single physical core provides a logical core for each of the threads that physical core is simultaneously multithreading), or a combination thereof (e.g., time sliced fetching and decoding and simultaneous multithreading thereafter such as in the Intel® Hyperthreading technology).

While register renaming is described in the context of out-of-order execution, it should be understood that register renaming may be used in an in-order architecture. While the illustrated embodiment of the processor also includes separate instruction and data cache units 734/774 and a shared L2 cache unit 776, alternative embodiments may have a single internal cache for both instructions and data, such as, for example, a Level 1 (L1) internal cache, or multiple levels of internal cache. In some embodiments, the system may include a combination of an internal cache and an external cache that is external to the core and/or the processor. Alternatively, all of the cache may be external to the core and/or the processor.

FIG. 8 is a block diagram of a processor 800 that may have more than one core, may have an integrated memory controller, and may have integrated graphics according to embodiments of the invention. The solid lined boxes in FIG. 8 illustrate a processor 800 with a single core 802A, a system agent 810, a set of one or more bus controller units 816, while the optional addition of the dashed lined boxes illustrates an alternative processor 800 with multiple cores 802A-N, a set of one or more integrated memory controller unit(s) 814 in the system agent unit 810, and special purpose logic 808.

Thus, different implementations of the processor 800 may include: 1) a CPU with the special purpose logic 808 being integrated graphics and/or scientific (throughput) logic (which may include one or more cores), and the cores 802A-N being one or more general purpose cores (e.g., general purpose in-order cores, general purpose out-of-order cores, a combination of the two); 2) a coprocessor with the cores 802A-N being a large number of special purpose cores intended primarily for graphics and/or scientific (throughput); and 3) a coprocessor with the cores 802A-N being a large number of general purpose in-order cores. Thus, the processor 800 may be a general-purpose processor, coprocessor or special-purpose processor, such as, for example, a network or communication processor, compression engine, graphics processor, GPGPU (general purpose graphics processing unit), a high-throughput many integrated core (MIC) coprocessor (including 30 or more cores), embedded processor, or the like. The processor may be implemented on one or more chips. The processor 800 may be a part of and/or may be implemented on one or more substrates using any of a number of process technologies, such as, for example, BiCMOS, CMOS, or N MOS.

The memory hierarchy includes one or more levels of cache within the cores, a set or one or more shared cache units 806, and external memory (not shown) coupled to the set of integrated memory controller units 814. The set of shared cache units 806 may include one or more mid-level caches, such as level 2 (L2), level 3 (L3), level 4 (L4), or other levels of cache, a last level cache (LLC), and/or combinations thereof. While in one embodiment a ring based interconnect unit 812 interconnects the integrated graphics logic 808, the set of shared cache units 806, and the system agent unit 810/integrated memory controller unit(s) 814, alternative embodiments may use any number of well-known techniques for interconnecting such units. In one embodiment, coherency is maintained between one or more cache units 806 and cores 802-A-N.

In some embodiments, one or more of the cores 802A-N are capable of multi-threading. The system agent 810 includes those components coordinating and operating cores 802A-N. The system agent unit 810 may include for example a power control unit (PCU) and a display unit. The PCU may be or include logic and components needed for regulating the power state of the cores 802A-N and the integrated graphics logic 808. The display unit is for driving one or more externally connected displays.

The cores 802A-N may be homogenous or heterogeneous in terms of architecture instruction set; that is, two or more of the cores 802A-N may be capable of execution the same instruction set, while others may be capable of executing only a subset of that instruction set or a different instruction set.

Referring now to FIG. 9, shown is a block diagram of a system 900 in accordance with one embodiment of the present invention. The system 900 may include one or more processors 910, 915, which are coupled to a controller hub 920. In one embodiment the controller hub 920 includes a graphics memory controller hub (GMCH) 990 and an Input/Output Hub (IOH) 950 (which may be on separate chips); the GMCH 990 includes memory and graphics controllers to which are coupled memory 940 and a coprocessor 945; the IOH 950 is couples input/output (I/O) devices 960 to the GMCH 990. Alternatively, one or both of the memory and graphics controllers are integrated within the processor (as described herein), the memory 940 and the coprocessor 945 are coupled directly to the processor 910, and the controller hub 920 in a single chip with the IOH 950.

The optional nature of additional processors 915 is denoted in FIG. 9 with broken lines. Each processor 910, 915 may include one or more of the processing cores described herein and may be some version of the processor 800.

The memory 940 may be, for example, dynamic random access memory (DRAM), phase change memory (PCM), or a combination of the two. For at least one embodiment, the controller hub 920 communicates with the processor(s) 910, 915 via a multi-drop bus, such as a frontside bus (FSB), point-to-point interface such as QuickPath Interconnect (QPI), or similar connection 995.

In one embodiment, the coprocessor 945 is a special-purpose processor, such as, for example, a high-throughput MIC processor, a network or communication processor, compression engine, graphics processor, GPGPU, embedded processor, or the like. In one embodiment, controller hub 920 may include an integrated graphics accelerator.

There can be a variety of differences between the physical resources 910, 915 in terms of a spectrum of metrics of merit including architectural, microarchitectural, thermal, power consumption characteristics, and the like.

In one embodiment, the processor 910 executes instructions that control data processing operations of a general type. Embedded within the instructions may be coprocessor instructions. The processor 910 recognizes these coprocessor instructions as being of a type that should be executed by the attached coprocessor 945. Accordingly, the processor 910 issues these coprocessor instructions (or control signals representing coprocessor instructions) on a coprocessor bus or other interconnect, to coprocessor 945. Coprocessor(s) 945 accept and execute the received coprocessor instructions.

Referring now to FIG. 10, shown is a block diagram of a first more specific exemplary system 1000 in accordance with an embodiment of the present invention. As shown in FIG. 10, multiprocessor system 1000 is a point-to-point interconnect system, and includes a first processor 1070 and a second processor 1080 coupled via a point-to-point interconnect 1050. Each of processors 1070 and 1080 may be some version of the processor 800. In one embodiment of the invention, processors 1070 and 1080 are respectively processors 910 and 915, while coprocessor 1038 is coprocessor 945. In another embodiment, processors 1070 and 1080 are respectively processor 910 coprocessor 945.

Processors 1070 and 1080 are shown including integrated memory controller (IMC) units 1072 and 1082, respectively. Processor 1070 also includes as part of its bus controller units point-to-point (P-P) interfaces 1076 and 1078; similarly, second processor 1080 includes P-P interfaces 1086 and 1088. Processors 1070, 1080 may exchange information via a point-to-point (P-P) interface 1050 using P-P interface circuits 1078, 1088. As shown in FIG. 10, IMCs 1072 and 1082 couple the processors to respective memories, namely a memory 1032 and a memory 1034, which may be portions of main memory locally attached to the respective processors.

Processors 1070, 1080 may each exchange information with a chipset 1090 via individual P-P interfaces 1052, 1054 using point to point interface circuits 1076, 1094, 1086, 1098. Chipset 1090 may optionally exchange information with the coprocessor 1038 via a high-performance interface 1039. In one embodiment, the coprocessor 1038 is a special-purpose processor, such as, for example, a high-throughput MIC processor, a network or communication processor, compression engine, graphics processor, GPGPU, embedded processor, or the like.

A shared cache (not shown) may be included in either processor or outside of both processors, yet connected with the processors via P-P interconnect, such that either or both processors' local cache information may be stored in the shared cache if a processor is placed into a low power mode.

Chipset 1090 may be coupled to a first bus 1016 via an interface 1096. In one embodiment, first bus 1016 may be a Peripheral Component Interconnect (PCI) bus, or a bus such as a PCI Express bus or another third generation I/O interconnect bus, although the scope of the present invention is not so limited.

As shown in FIG. 10, various I/O devices 1014 may be coupled to first bus 1016, along with a bus bridge 1018 which couples first bus 1016 to a second bus 1020. In one embodiment, one or more additional processor(s) 1015, such as coprocessors, high-throughput MIC processors, GPGPU's, accelerators (such as, e.g., graphics accelerators or digital signal processing (DSP) units), field programmable gate arrays, or any other processor, are coupled to first bus 1016. In one embodiment, second bus 1020 may be a low pin count (LPC) bus. Various devices may be coupled to a second bus 1020 including, for example, a keyboard and/or mouse 1022, communication devices 1027 and a storage unit 1028 such as a disk drive or other mass storage device which may include instructions/code and data 1030, in one embodiment. Further, an audio I/O 1024 may be coupled to the second bus 1020. Note that other architectures are possible. For example, instead of the point-to-point architecture of FIG. 10, a system may implement a multi-drop bus or other such architecture.

Referring now to FIG. 11, shown is a block diagram of a SoC 1100 in accordance with an embodiment of the present invention. Similar elements in FIG. 8 bear like reference numerals. Also, dashed lined boxes are optional features on more advanced SoCs. In FIG. 11, an interconnect unit(s) 1102 is coupled to: an application processor 1110 which includes a set of one or more cores 1102A-N and shared cache unit(s) 1106; a system agent unit 1110; a bus controller unit(s) 1116; an integrated memory controller unit(s) 1114; a set or one or more coprocessors 1120 which may include integrated graphics logic, an image processor, an audio processor, and a video processor; an static random access memory (SRAM) unit 1130; a direct memory access (DMA) unit 1132; and a display unit 1140 for coupling to one or more external displays. In one embodiment, the coprocessor(s) 1120 include a special-purpose processor, such as, for example, a network or communication processor, compression engine, GPGPU, a high-throughput MIC processor, embedded processor, or the like.

Embodiments of the mechanisms disclosed herein may be implemented in hardware, software, firmware, or a combination of such implementation approaches. Embodiments of the invention may be implemented as computer programs or program code executing on programmable systems comprising at least one processor, a storage system (including volatile and non-volatile memory and/or storage elements), at least one input device, and at least one output device.

Program code, such as code 1030 illustrated in FIG. 10, may be applied to input instructions to perform the functions described herein and generate output information. The output information may be applied to one or more output devices, in known fashion. For purposes of this application, a processing system includes any system that has a processor, such as, for example; a digital signal processor (DSP), a microcontroller, an application specific integrated circuit (ASIC), or a microprocessor.

The program code may be implemented in a high level procedural or object oriented programming language to communicate with a processing system. The program code may also be implemented in assembly or machine language, if desired. In fact, the mechanisms described herein are not limited in scope to any particular programming language. In any case, the language may be a compiled or interpreted language.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritable's (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, embodiments of the invention also include non-transitory, tangible machine-readable media containing instructions or containing design data, such as Hardware Description Language (HDL), which defines structures, circuits, apparatuses, processors and/or system features described herein. Such embodiments may also be referred to as program products.

The flowcharts and block diagrams in the FIGURES illustrate the architecture, functionality, and operation of possible implementations of systems, methods and computer program products according to various aspects of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order or alternative orders, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The foregoing disclosure outlines features of several embodiments so that those skilled in the art may better understand various aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

All or part of any hardware element disclosed herein may readily be provided in a system-on-a-chip (SoC), including a central processing unit (CPU) package. An SoC represents an integrated circuit (IC) that integrates components of a computer or other electronic system into a single chip. The SoC may contain digital, analog, mixed-signal, and radio frequency functions, all of which may be provided on a single chip substrate. Other embodiments may include a multi-chip-module (MCM), with a plurality of chips located within a single electronic package and configured to interact closely with each other through the electronic package. In various other embodiments, the computing functionalities disclosed herein may be implemented in one or more silicon cores in Application Specific Integrated Circuits (ASICs), Field Programmable Gate Arrays (FPGAs), and other semiconductor chips.

As used throughout this specification, the term “processor” or “microprocessor” should be understood to include not only a traditional microprocessor (such as Intel's® industry-leading x86 and x64 architectures), but also graphics processors, matrix processors, and any ASIC, FPGA, microcontroller, digital signal processor (DSP), programmable logic device, programmable logic array (PLA), microcode, instruction set, emulated or virtual machine processor, or any similar “Turing-complete” device, combination of devices, or logic elements (hardware or software) that permit the execution of instructions.

Note also that in certain embodiments, some of the components may be omitted or consolidated. In a general sense, the arrangements depicted in the figures should be understood as logical divisions, whereas a physical architecture may include various permutations, combinations, and/or hybrids of these elements. It is imperative to note that countless possible design configurations can be used to achieve the operational objectives outlined herein. Accordingly, the associated infrastructure has a myriad of substitute arrangements, design choices, device possibilities, hardware configurations, software implementations, and equipment options.

In a general sense, any suitably-configured processor can execute instructions associated with data or microcode to achieve the operations detailed herein. Any processor disclosed herein could transform an element or an article (for example, data) from one state or thing to another state or thing. In another example, some activities outlined herein may be implemented with fixed logic or programmable logic (for example, software and/or computer instructions executed by a processor) and the elements identified herein could be some type of a programmable processor, programmable digital logic (for example, a field programmable gate array (FPGA), an erasable programmable read only memory (EPROM), an electrically erasable programmable read only memory (EEPROM)), an ASIC that includes digital logic, software, code, electronic instructions, flash memory, optical disks, CD-ROMs, DVD ROMs, magnetic or optical cards, other types of machine-readable mediums suitable for storing electronic instructions, or any suitable combination thereof.

In operation, a storage may store information in any suitable type of tangible, non-transitory storage medium (for example, random access memory (RAM), read only memory (ROM), field programmable gate array (FPGA), erasable programmable read only memory (EPROM), electrically erasable programmable ROM (EEPROM), or microcode), software, hardware (for example, processor instructions or microcode), or in any other suitable component, device, element, or object where appropriate and based on particular needs. Furthermore, the information being tracked, sent, received, or stored in a processor could be provided in any database, register, table, cache, queue, control list, or storage structure, based on particular needs and implementations, all of which could be referenced in any suitable timeframe. Any of the memory or storage elements disclosed herein should be construed as being encompassed within the broad terms ‘memory’ and ‘storage,’ as appropriate. A non-transitory storage medium herein is expressly intended to include any non-transitory special-purpose or programmable hardware configured to provide the disclosed operations, or to cause a processor to perform the disclosed operations. A non-transitory storage medium also expressly includes a processor having stored thereon hardware-coded instructions, and optionally microcode instructions or sequences encoded in hardware, firmware, or software.

Computer program logic implementing all or part of the functionality described herein is embodied in various forms, including, but in no way limited to, hardware description language, a source code form, a computer executable form, machine instructions or microcode, programmable hardware, and various intermediate forms (for example, forms generated by an HDL processor, assembler, compiler, linker, or locator). In an example, source code includes a series of computer program instructions implemented in various programming languages, such as an object code, an assembly language, or a high-level language such as OpenCL, FORTRAN, C, C++, JAVA, or HTML for use with various operating systems or operating environments, or in hardware description languages such as Spice, Verilog, and VHDL. The source code may define and use various data structures and communication messages. The source code may be in a computer executable form (e.g., via an interpreter), or the source code may be converted (e.g., via a translator, assembler, or compiler) into a computer executable form, or converted to an intermediate form such as byte code. Where appropriate, any of the foregoing may be used to build or describe appropriate discrete or integrated circuits, whether sequential, combinatorial, state machines, or otherwise.

In one example, any number of electrical circuits of the FIGURES may be implemented on a board of an associated electronic device. The board can be a general circuit board that can hold various components of the internal electronic system of the electronic device and, further, provide connectors for other peripherals. More specifically, the board can provide the electrical connections by which the other components of the system can communicate electrically. Any suitable processor and memory can be suitably coupled to the board based on particular configuration needs, processing demands, and computing designs.

Other components such as external storage, additional sensors, controllers for audio/video display, and peripheral devices may be attached to the board as plug-in cards, via cables, or integrated into the board itself. In another example, the electrical circuits of the FIGURES may be implemented as stand-alone modules (e.g., a device with associated components and circuitry configured to perform a specific application or function) or implemented as plug-in modules into application specific hardware of electronic devices.

Note that with the numerous examples provided herein, interaction may be described in terms of two, three, four, or more electrical components. However, this has been done for purposes of clarity and example only. It should be appreciated that the system can be consolidated or reconfigured in any suitable manner. Along similar design alternatives, any of the illustrated components, modules, and elements of the FIGURES may be combined in various possible configurations, all of which are within the broad scope of this specification. In certain cases, it may be easier to describe one or more of the functionalities of a given set of flows by only referencing a limited number of electrical elements. It should be appreciated that the electrical circuits of the FIGURES and its teachings are readily scalable and can accommodate a large number of components, as well as more complicated/sophisticated arrangements and configurations.

Accordingly, the examples provided should not limit the scope or inhibit the broad teachings of the electrical circuits as potentially applied to a myriad of other architectures.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

### Example Implementations

The following examples pertain to embodiments described throughout this disclosure.

One or more embodiments may include an apparatus, comprising: a processor; and a memory controller; wherein the processor comprises hint generation circuitry to: identify a memory access operation, wherein the memory access operation comprises an operation associated with a memory location of a memory, and wherein the memory comprises a plurality of memory banks; determine that a cache memory does not contain data associated with the memory location; send a memory access notification to the memory controller via a first transmission path, wherein the memory access notification comprises a notification associated with access to the memory location; and send a memory access request to the memory controller via a second transmission path, wherein the memory access request comprises a request associated with access to the memory location, and wherein the second transmission path is slower than the first transmission path; wherein the memory controller comprises speculative activation circuitry to: receive the memory access notification via the first transmission path; and send a memory activation request based on the memory access notification, wherein the memory activation request comprises a request to activate a memory bank associated with the memory location, wherein the memory bank is identified from the plurality of memory banks.

In one example embodiment of an apparatus, the first transmission path comprises a dedicated transmission link to the memory controller, wherein the dedicated transmission link is not used in the second transmission path.

In one example embodiment of an apparatus, the second transmission path comprises a queue of memory access requests, and the first transmission path does not comprise the queue of memory access requests.

In one example embodiment of an apparatus, the second transmission path comprises a second cache memory, and the first transmission path does not comprise the second cache memory.

In one example embodiment of an apparatus, the first transmission path and the second transmission path comprise a shared transmission link to the memory controller, wherein the shared transmission link is used in the first transmission path and the second transmission path.

In one example embodiment of an apparatus, the hint generation circuitry to send the memory access notification to the memory controller via the first transmission path is further to send the memory access notification over the shared transmission link with a pending memory access request on the second transmission path.

In one example embodiment of an apparatus, the speculative activation circuitry to send the memory activation request based on the memory access notification is further to: identify a memory page associated with the memory location; identify a set of memory banks associated with the memory page, wherein the set of memory banks is identified from the plurality of memory banks; and send a plurality of memory activation requests, wherein the plurality of memory activation requests comprises a plurality of requests to activate the set of memory banks.

In one example embodiment of an apparatus, the speculative activation circuitry to identify the set of memory banks associated with the memory page is further to: determine that a memory bandwidth usage is below a threshold; and identify the set of memory banks comprising each memory bank of the plurality of memory banks that is associated with the memory page.

In one example embodiment of an apparatus, the speculative activation circuitry to identify the set of memory banks associated with the memory page is further to: determine that a memory bandwidth usage is above a threshold; and identify the set of memory banks comprising a subset of each memory bank of the plurality of memory banks that is associated with the memory page.

In one example embodiment of an apparatus, the memory controller is to: identify a memory write operation; determine that a write flush usage is below a threshold; determine that a particular memory bank associated with the memory write operation is active; and block the memory write operation.

In one example embodiment of an apparatus, the memory controller is to: identify a memory write operation; determine that a write flush usage is below a threshold; determine that a particular memory bank associated with the memory write operation is inactive; and perform the memory write operation.

In one example embodiment of an apparatus, the memory controller is to: identify a memory refresh operation; determine that a memory refresh usage is below a threshold; determine that a particular memory bank associated with the memory refresh operation is active; and block the memory refresh operation.

In one example embodiment of an apparatus, the memory controller is to: identify a memory refresh operation; determine that a memory refresh usage is below a threshold; determine that a particular memory bank associated with the memory refresh operation is inactive; and perform the memory refresh operation.

In one example embodiment of an apparatus, the memory controller is further to: access a data block of the memory bank associated with the memory location; and store the data block in a prefetch buffer.

In one example embodiment of an apparatus, the memory access notification comprises a hint for a speculative memory activation.

One or more embodiments may include at least one machine accessible storage medium having instructions stored thereon, wherein the instructions, when executed on a machine, cause the machine to: identify a memory access operation, wherein the memory access operation comprises an operation associated with a memory location of a memory, and wherein the memory comprises a plurality of memory banks; determine that a cache memory does not contain data associated with the memory location; send a memory access notification to a memory controller via a first transmission path, wherein the memory access notification comprises a notification associated with access to the memory location; send a memory access request to the memory controller via a second transmission path, wherein the memory access request comprises a request associated with access to the memory location, and wherein the second transmission path is slower than the first transmission path; receive the memory access notification at the memory controller via the first transmission path; and send a memory activation request based on the memory access notification, wherein the memory activation request comprises a request to activate a memory bank associated with the memory location, wherein the memory bank is identified from the plurality of memory banks.

In one example embodiment of a storage medium, the first transmission path comprises a dedicated transmission link to the memory controller, wherein the dedicated transmission link is not used in the second transmission path.

In one example embodiment of a storage medium, the second transmission path comprises a queue of memory access requests, and wherein the first transmission path does not comprise the queue of memory access requests.

In one example embodiment of a storage medium, the second transmission path comprises a second cache memory, and wherein the first transmission path does not comprise the second cache memory.

In one example embodiment of a storage medium, the first transmission path and the second transmission path comprise a shared transmission link to the memory controller, wherein the shared transmission link is used in the first transmission path and the second transmission path.

In one example embodiment of a storage medium, the instructions that cause the machine to send the memory access notification to the memory controller via the first transmission path further cause the machine to send the memory access notification over the shared transmission link with a pending memory access request on the second transmission path.

In one example embodiment of a storage medium, the instructions that cause the machine to send the memory activation request based on the memory access notification further cause the machine to: identify a memory page associated with the memory location; identify a set of memory banks associated with the memory page, wherein the set of memory banks is identified from the plurality of memory banks; and send a plurality of memory activation requests, wherein the plurality of memory activation requests comprises a plurality of requests to activate the set of memory banks.

One or more embodiments may include a system, comprising: a memory comprising a plurality of memory banks; a cache; an interconnect to provide a first transmission path and a second transmission path, wherein the first transmission path is faster than the second transmission path; a processor to: identify a memory access operation, wherein the memory access operation comprises an operation associated with a memory location of the memory; determine that the cache does not contain data associated with the memory location; send a memory access notification to a memory controller via the first transmission path, wherein the memory access notification comprises a notification associated with access to the memory location; and send a memory access request to the memory controller via the second transmission path, wherein the memory access request comprises a request associated with access to the memory location; and the memory controller to: receive the memory access notification via the first transmission path; and send a memory activation request based on the memory access notification, wherein the memory activation request comprises a request to activate a memory bank associated with the memory location, wherein the memory bank is identified from the plurality of memory banks.

In one example embodiment of a system, the system further comprises a second cache and a memory request queue, wherein the second cache and the memory request queue are on the second transmission path.

One or more embodiments may include a method, comprising: identifying a memory access operation, wherein the memory access operation comprises an operation associated with a memory location of a memory, and wherein the memory comprises a plurality of memory banks; determining that a cache memory does not contain data associated with the memory location; sending a memory access notification to a memory controller via a first transmission path, wherein the memory access notification comprises a notification associated with access to the memory location; sending a memory access request to the memory controller via a second transmission path, wherein the memory access request comprises a request associated with access to the memory location, and wherein the second transmission path is slower than the first transmission path; receiving the memory access notification at the memory controller via the first transmission path; and sending a memory activation request based on the memory access notification, wherein the memory activation request comprises a request to activate a memory bank associated with the memory location, wherein the memory bank is identified from the plurality of memory banks.

In one example embodiment of a method, the method further comprises: identifying a memory page associated with the memory location; identifying a set of memory banks associated with the memory page, wherein the set of memory banks is identified from the plurality of memory banks; and sending a plurality of memory activation requests, wherein the plurality of memory activation requests comprises a plurality of requests to activate the set of memory banks.

1.-25. (canceled)

26. An apparatus, comprising:
a processor; and
a memory controller;
wherein the processor comprises hint generation circuitry to:
identify a memory access operation, wherein the memory access operation comprises an operation associated with a memory location of a memory, and wherein the memory comprises a plurality of memory banks;
determine that a cache memory does not contain data associated with the memory location;
send a memory access notification to the memory controller via a first transmission path, wherein the memory access notification comprises a notification associated with access to the memory location; and
send a memory access request to the memory controller via a second transmission path, wherein the memory access request comprises a request associated with access to the memory location, and wherein the second transmission path is slower than the first transmission path;
wherein the memory controller comprises speculative activation circuitry to:
receive the memory access notification via the first transmission path; and
send a memory activation request based on the memory access notification, wherein the memory activation request comprises a request to activate a memory bank associated with the memory location, wherein the memory bank is identified from the plurality of memory banks.

27. The apparatus of claim 26, wherein the first transmission path comprises a dedicated transmission link to the memory controller, wherein the dedicated transmission link is not used in the second transmission path.

28. The apparatus of claim 26, wherein the second transmission path comprises a queue of memory access requests, and wherein the first transmission path does not comprise the queue of memory access requests.

29. The apparatus of claim 26, wherein the second transmission path comprises a second cache memory, and wherein the first transmission path does not comprise the second cache memory.

30. The apparatus of claim 26, wherein the first transmission path and the second transmission path comprise a shared transmission link to the memory controller, wherein the shared transmission link is used in the first transmission path and the second transmission path.

31. The apparatus of claim 30, wherein the hint generation circuitry to send the memory access notification to the memory controller via the first transmission path is further to send the memory access notification over the shared transmission link with a pending memory access request on the second transmission path.

32. The apparatus of claim 26, wherein the speculative activation circuitry to send the memory activation request based on the memory access notification is further to:
identify a memory page associated with the memory location;
identify a set of memory banks associated with the memory page, wherein the set of memory banks is identified from the plurality of memory banks; and
send a plurality of memory activation requests, wherein the plurality of memory activation requests comprises a plurality of requests to activate the set of memory banks.

33. The apparatus of claim 32, wherein the speculative activation circuitry to identify the set of memory banks associated with the memory page is further to:
determine that a memory bandwidth usage is below a threshold; and
identify the set of memory banks comprising each memory bank of the plurality of memory banks that is associated with the memory page.

34. The apparatus of claim 32, wherein the speculative activation circuitry to identify the set of memory banks associated with the memory page is further to:
determine that a memory bandwidth usage is above a threshold; and
identify the set of memory banks comprising a subset of each memory bank of the plurality of memory banks that is associated with the memory page.

35. The apparatus of claim 26, wherein the memory controller is to:
identify a memory write operation;
determine that a write flush usage is below a threshold;
determine that a particular memory bank associated with the memory write operation is active; and
block the memory write operation.

36. The apparatus of claim 26, wherein the memory controller is to:
identify a memory write operation;
determine that a write flush usage is below a threshold;
determine that a particular memory bank associated with the memory write operation is inactive; and
perform the memory write operation.

37. The apparatus of claim 26, wherein the memory controller is to:
identify a memory refresh operation;
determine that a memory refresh usage is below a threshold;
determine that a particular memory bank associated with the memory refresh operation is active; and
block the memory refresh operation.

38. The apparatus of claim 26, wherein the memory controller is to:
identify a memory refresh operation;
determine that a memory refresh usage is below a threshold;
determine that a particular memory bank associated with the memory refresh operation is inactive; and
perform the memory refresh operation.

39. The apparatus of claim 26, wherein the memory controller is to:
access a data block of the memory bank associated with the memory location; and
store the data block in a prefetch buffer.

40. The apparatus of claim 26, wherein the memory access notification comprises a hint for a speculative memory activation.

41. At least one machine accessible storage medium having instructions stored thereon, wherein the instructions, when executed on a machine, cause the machine to:
identify a memory access operation, wherein the memory access operation comprises an operation associated with a memory location of a memory, and wherein the memory comprises a plurality of memory banks;
determine that a cache memory does not contain data associated with the memory location;
send a memory access notification to a memory controller via a first transmission path, wherein the memory access notification comprises a notification associated with access to the memory location;
send a memory access request to the memory controller via a second transmission path, wherein the memory access request comprises a request associated with access to the memory location, and wherein the second transmission path is slower than the first transmission path;
receive the memory access notification at the memory controller via the first transmission path; and
send a memory activation request based on the memory access notification, wherein the memory activation request comprises a request to activate a memory bank associated with the memory location, wherein the memory bank is identified from the plurality of memory banks.

42. The storage medium of claim 41, wherein the first transmission path comprises a dedicated transmission link to the memory controller, wherein the dedicated transmission link is not used in the second transmission path.

43. The storage medium of claim 41, wherein the second transmission path comprises a queue of memory access requests, and wherein the first transmission path does not comprise the queue of memory access requests.

44. The storage medium of claim 41, wherein the second transmission path comprises a second cache memory, and wherein the first transmission path does not comprise the second cache memory.

45. The storage medium of claim 41:
wherein the first transmission path and the second transmission path comprise a shared transmission link to the memory controller, wherein the shared transmission link is used in the first transmission path and the second transmission path; and
wherein the instructions that cause the machine to send the memory access notification to the memory controller via the first transmission path further cause the machine to send the memory access notification over the shared transmission link with a pending memory access request on the second transmission path.

46. The storage medium of claim 41, wherein the instructions that cause the machine to send the memory activation request based on the memory access notification further cause the machine to:
identify a memory page associated with the memory location;
identify a set of memory banks associated with the memory page, wherein the set of memory banks is identified from the plurality of memory banks; and
send a plurality of memory activation requests, wherein the plurality of memory activation requests comprises a plurality of requests to activate the set of memory banks.

47. A system, comprising:
a memory comprising a plurality of memory banks;
a cache;
an interconnect to provide a first transmission path and a second transmission path, wherein the first transmission path is faster than the second transmission path;
a processor to:
identify a memory access operation, wherein the memory access operation comprises an operation associated with a memory location of the memory;
determine that the cache does not contain data associated with the memory location;
send a memory access notification to a memory controller via the first transmission path, wherein the memory access notification comprises a notification associated with access to the memory location; and
send a memory access request to the memory controller via the second transmission path, wherein the memory access request comprises a request associated with access to the memory location; and
the memory controller to:
receive the memory access notification via the first transmission path; and
send a memory activation request based on the memory access notification, wherein the memory activation request comprises a request to activate a memory bank associated with the memory location, wherein the memory bank is identified from the plurality of memory banks.

48. The system of claim 47, further comprising a second cache and a memory request queue, wherein the second cache and the memory request queue are on the second transmission path.

49. A method, comprising:
identifying a memory access operation, wherein the memory access operation comprises an operation associated with a memory location of a memory, and wherein the memory comprises a plurality of memory banks;
determining that a cache memory does not contain data associated with the memory location;
sending a memory access notification to a memory controller via a first transmission path, wherein the memory access notification comprises a notification associated with access to the memory location;
sending a memory access request to the memory controller via a second transmission path, wherein the memory access request comprises a request associated with access to the memory location, and wherein the second transmission path is slower than the first transmission path;
receiving the memory access notification at the memory controller via the first transmission path; and
sending a memory activation request based on the memory access notification, wherein the memory activation request comprises a request to activate a memory bank associated with the memory location, wherein the memory bank is identified from the plurality of memory banks.

50. The method of claim 49, further comprising:
identifying a memory page associated with the memory location;
identifying a set of memory banks associated with the memory page, wherein the set of memory banks is identified from the plurality of memory banks; and
sending a plurality of memory activation requests, wherein the plurality of memory activation requests comprises a plurality of requests to activate the set of memory banks.
